(19) United States
(12) Patent Application Publication
(10) Pub. No.: US 2014/0217490 A1
(43) Pub. Date: Aug. 7, 2014

(54) NONVOLATILE MEMORY DEVICE AND METHOD OF FABRICATING THE SAME

(71) Applicant: SAMSUNG ELECTRONICS CO., LTD., Suwon-si (KR)

(72) Inventors: Bo-Young Seo, Suwon-si (KR); Weon-Ho Park, Hwaseong-si (KR); Chang-Min Jeon, Yongin-si (KR); Yong-Sang Cho, Hwaseong-si (KR)

(73) Assignee: Samsung Electronics Co., Ltd., Suwon-si (KR)

(21) Appl. No.: 13/803,791

(22) Filed: Mar. 14, 2013

(30) Foreign Application Priority Data
Feb. 4, 2013 (KR) 10-2013-0012495

(51) Int. Cl. H01L 29/788

(52) U.S. Cl. CPC H01L 29/788
USPC 257/319

(57) ABSTRACT

In a nonvolatile memory device and a method for fabricating the same, a device comprises a substrate, a trench in the substrate and a first gate pattern comprising a first bottom gate electrode having a first portion in the trench and having a second portion on the first portion and protruding in an upward direction relative to an upper surface of the substrate. A second gate pattern comprising a second gate electrode is on the substrate at a side of the first gate pattern and insulated from the first gate pattern. An impurity region is present in the substrate at a side of the first gate pattern opposite the second gate pattern, and overlapping part of the trench.

This application claims priority from Korean Patent Application No. 10-2013-0012495 filed on Feb. 4, 2013 in the Korean Intellectual Property Office, the disclosure of which is incorporated herein by reference in its entirety.

### BACKGROUND

1. Field

The present inventive concepts relate to a nonvolatile memory device and a method of fabricating the same.

2. Description of the Related Art

Semiconductor memory devices are broadly classified into volatile memory devices and nonvolatile memory devices.

Volatile memory devices are characterized by the fact that they lose stored data when the power supply to the device is turned off. Examples of the volatile memory devices include static random access memories (SRAMs), dynamic random access memories (DRAMs), and synchronous dynamic random access memories (SDRAMs). On the other hand, nonvolatile memory devices retain stored data, even when the power supply is interrupted. Examples of nonvolatile memory devices include read-only memories (ROMs), programmable read-only memories (PROMs), erasable programmable read-only memories (EPROMs), electrically erasable programmable read-only memories (EEPROMs), flash memories, and nonvolatile memories that utilize a programmable resistance material, such as phase-change random access memories (PRAMs), ferroelectric random access memories (FRAMs), and resistive random access memories (RRAMs).

### SUMMARY

Aspects of the present inventive concepts provide a nonvolatile memory device which can improve the efficiency of erase and program operations using an edge structure formed in a substrate. As a result, the resulting device can operate with increased reliability, and can be further reduction in size through integration.

Aspects of the present inventive concepts also provide a method of fabricating the nonvolatile memory device.

In one aspect, a nonvolatile memory device comprises: a substrate; a trench in the substrate; a first gate pattern comprising a first bottom gate electrode having a first portion in the trench and having a second portion on the first portion and protruding in an upward direction relative to an upper surface of the substrate; a second gate pattern comprising a second gate electrode on the substrate at a side of the first gate pattern and insulated from the first gate pattern; and an impurity region in the substrate at a side of the first gate pattern opposite the second gate pattern, and overlapping part of the trench.

In some embodiments, the trench has a first width, and the second portion of the first bottom gate electrode has a second width, wherein the first width is less than the second width.

In some embodiments, the trench is entirely overlapped by the second portion of the first bottom gate electrode.

In some embodiments, the impurity region covers at least a portion of a bottom surface of the trench and a side surface of the trench.

In some embodiments, the first gate pattern further comprises a first gate insulating layer between the trench and the first portion of the first bottom gate electrode and a first top gate electrode on the first bottom gate electrode, wherein each of the first top gate electrode and the first bottom gate electrode does not overlap the second gate electrode.

In some embodiments, the first gate insulating layer is conformally formed in the trench.

In some embodiments, the first gate insulating layer comprises a first bottom gate insulating layer on the bottom surface of the trench, wherein the first bottom gate insulating layer is thinnest at regions at which the bottom surface of the trench meets a side surface of the trench.

In some embodiments, the first gate pattern further comprises an inter-electrode insulating layer interposed between the first bottom gate electrode and the first top gate electrode, the first gate pattern comprises a memory transistor gate, and the second gate pattern comprises a selection transistor gate.

In some embodiments, the first gate pattern further comprises a first gate insulating layer between the trench and the first portion of the first bottom gate electrode, and the second gate pattern further comprises a second gate insulating layer, wherein each of the first gate insulating layer and the second gate insulating layer comprises silicon oxide, and a thickness of the first gate insulating layer is different from a thickness of the second gate insulating layer.

In some embodiments, the thickness of the first gate insulating layer is greater than the thickness of the second gate insulating layer.

In some embodiments, the first gate pattern further comprises a spacer which is on the substrate adjacent to the impurity region and is at a side surface of the first gate pattern, wherein the trench is overlapped by a portion of the spacer.

In another aspect, a nonvolatile memory device comprises: a substrate; a first gate pattern comprising: a first bottom gate electrode having a first portion buried in the substrate and a second portion on the substrate; and a first top gate electrode on the first bottom gate electrode; a second gate pattern comprising a second gate electrode on the substrate adjacent a side of the first gate pattern; and an impurity region in the substrate at a side of the first gate pattern opposite the second gate pattern, and under at least a portion of the first portion of the first bottom gate electrode, wherein the first portion of the first bottom gate electrode is narrower than the second portion of the first bottom gate electrode, and wherein a threshold voltage of the second gate pattern is different than a threshold voltage of the first gate pattern.

In some embodiments, the first portion of the first bottom gate electrode is entirely overlapped by the second portion.

In some embodiments, the substrate comprises a trench formed therein, the first portion of the first bottom gate electrode fills the trench, and the impurity region covers at least a portion of a bottom surface of the trench and a side surface of the trench.

In some embodiments, the first bottom gate electrode, the first top gate electrode, and the second gate electrode comprise polysilicon.

In another aspect, a nonvolatile memory device comprises: a substrate having a trench; a first gate of a memory transistor on the substrate, a first portion of the first gate partially in the trench and partially above the trench; a second portion of the first gate on the first portion and insulated from the first portion by an intergate insulating layer, the first portion of the first gate being insulated from the trench by a first gate insulating layer; a second gate of a selection transistor on the substrate at a side of the first gate, the second gate insulated from the first gate by a blocking insulating layer, and the second gate insulated from the substrate by a second gate insulating layer; and an impurity region in the substrate at a side of the trench, the impurity region positioned at a side of the first gate opposite the second gate.

In some embodiments, the trench has a bottom and a sidewall and wherein the impurity region is further positioned in the substrate at the sidewall and at least a portion of the bottom of the trench so that the portion of the first portion of the first gate that is partially in the trench is at least partially on the impurity region.

In some embodiments, the first gate insulating layer and the second gate insulating layer have different thicknesses.

In some embodiments, the first portion of the first gate comprises a charge storage region of the memory transistor and wherein the second portion of the first gate comprises a control gate of the memory transistor.

In some embodiments, the trench has a bottom and a sidewall and wherein the first gate insulating layer is relatively thinner at a region of the trench where the bottom and sidewall interface.

### BRIEF DESCRIPTION OF THE DRAWINGS

The above and other aspects and features of the present inventive concepts will become more apparent by describing in detail exemplary embodiments thereof with reference to the attached drawings, in which:

FIG. 1 is a diagram illustrating a memory cell array of a nonvolatile memory device according to embodiments of the present inventive concepts;

FIG. 2 is a layout view of a nonvolatile memory device according to an embodiment of the present inventive concepts;

FIG. 3 is a cross-sectional view of the nonvolatile memory device shown in FIG. 2;

FIG. 4 is a cross-sectional view of a modified example of the nonvolatile memory device according to the embodiment of FIGS. 2 and 3;

FIG. 5 is a cross-sectional view of a nonvolatile memory device according to another embodiment of the present inventive concepts;

FIGS. 6A through 14 are views illustrating intermediate processes included in a method of fabricating a nonvolatile memory device according to an embodiment of the present inventive concepts;

FIGS. 15 and 16 are views illustrating intermediate processes included in a method of fabricating a nonvolatile memory device according to another embodiment of the present inventive concepts;

FIG. 17 is a block diagram of a memory system including a nonvolatile memory device according to some embodiments of the present inventive concepts;

FIG. 18 is a block diagram of an application example of the memory system shown in FIG. 17; and

FIG. 19 is a block diagram of a computing system including the memory system of FIG. 18.

### DETAILED DESCRIPTION OF THE EMBODIMENTS

The present inventive concepts will now be described more fully hereinafter with reference to the accompanying drawings, in which preferred embodiments of the inventive concepts are shown. This inventive concepts may, however, be embodied in different forms and should not be construed as limited to the embodiments set forth herein. Rather, these embodiments are provided so that this disclosure will be thorough and complete, and will convey the scope of the inventive concepts to those skilled in the art. The same reference numbers indicate the same components throughout the specification. In the attached figures, the thickness of layers and regions is exaggerated for clarity.

It will be understood that when an element or layer is referred to as being “connected to,” or “coupled to” another element or layer, it can be directly connected to or coupled to another element or layer or intervening elements or layers may be present. In contrast, when an element is referred to as being “directly connected to” or “directly coupled to” another element or layer, there are no intervening elements or layers present. Like numbers refer to like elements throughout. As used herein, the term “and/or” includes any and all combinations of one or more of the associated listed items.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concepts.

The use of the terms “a” and “an” and “the” and similar referents in the context of describing the inventive concepts (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this inventive concepts belongs. It is noted that the use of any and all examples, or exemplary terms provided herein is intended merely to better illuminate the inventive concepts and is not a limitation on the scope of the inventive concepts unless otherwise specified. Further, unless defined otherwise, all terms defined in generally used dictionaries may not be overly interpreted.

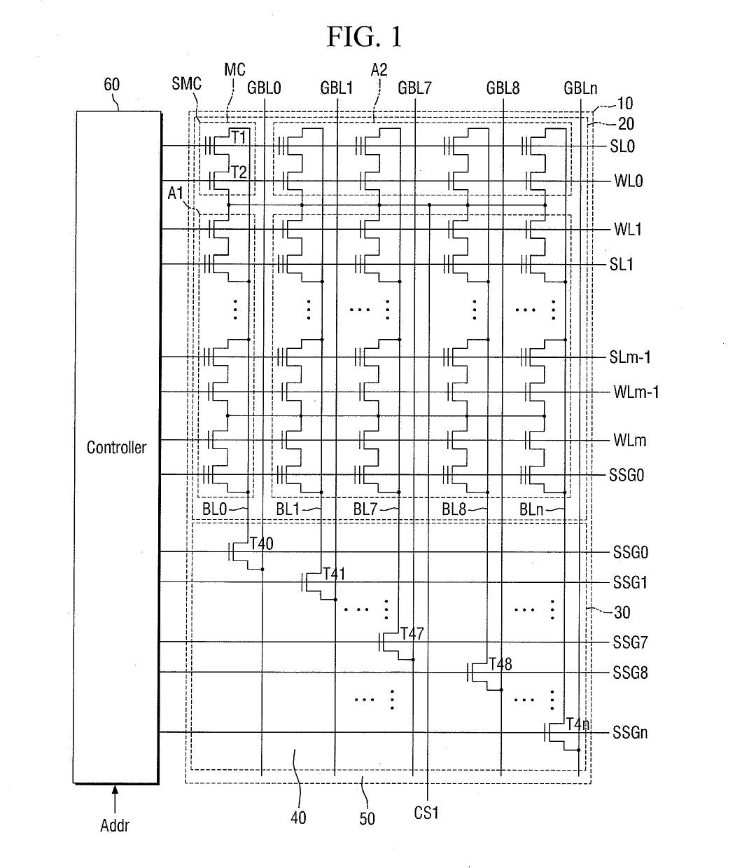

Hereinafter, a memory cell array of a nonvolatile memory device according to embodiments of the present inventive concepts will be described with reference to FIG. 1.

FIG. 1 is a diagram illustrating a memory cell array 10 of a nonvolatile memory device according to embodiments of the present inventive concepts.

In FIG. 1, a memory cell as including a pair of transistors, a single selection transistor and a single memory transistor. However, this configuration is merely an example that is used for ease of description, and it is to be understood that the present inventive concepts are not limited to this example. In an example of an alternative embodiment, a plurality of memory transistors can be connected to a single selection transistor to form a memory cell of the nonvolatile memory device. In other examples, other configurations can be employed.

Referring to FIG. 1, the memory cell array 10 of the nonvolatile memory device includes at least one memory cell block 20 (also referred to as a “sector”) and a bit line selection switching block 30.

The memory cell block 20 includes a plurality of memory cells MC arranged in a matrix. Each of the memory cells MC may include two transistors, that is, a memory transistor T1 and a selection transistor T2. The memory transistor T1 preserves data, and the selection transistor T2 operates to select the memory transistor T1. The memory transistor T1 may comprise, in some embodiments, a floating gate tunnel oxide-type transistor which includes a floating gate FG and a control gate CG. The selection transistor T2 may include a selection gate SG.

The selection transistor T2 in each of the memory cells MC is connected between each of a plurality of word lines WL0 through WLm which extend in a row direction and each of a plurality of bit lines BL0 through BLn which extend in a column direction. The memory transistor T1 in each of the memory cells MC is placed between each of a plurality of selection lines SL0 through SLm which extend in the row direction and each of the bit lines BL0 through BLn which extend in the column direction. In this manner, the control gates CG of the memory transistors T1 arranged in each row of in the memory cell block 20 are connected commonly to a corresponding one of the selection lines SL0 through SLm. In addition, the selection gates SG of the selection transistors T2 arranged in each row of the memory cell block 20 are connected commonly to a corresponding one of the word lines WL0 through WLm.

The selection transistor T2 has a first terminal connected to the memory transistor T1 and a second terminal connected to a common source line CS1. The common source line CS1 may be provided for each row, column or sector of the memory cell array 10 or for the entire memory, depending on the application.

The bit line selection switching block 30 includes a plurality of bit line selection switches T40 through T4n, each selecting a column of memory cells MC. Each of the bit line selection switches T40 through T4n may be implemented in the form of a switching transistor for a predetermined number of memory cells MC (e.g., m memory cells MC, where m is a natural number) arranged in the column direction. The bit line selection switches T40 through T4n respectively connect a plurality of global bit lines GBL0 through GBLn to the local bit lines BL0 through BLn and are controlled respectively by bit line selection switch lines SSG0 through SSGn which extend in the row direction to be parallel to the word lines WL0 through WLm.

The bit line selection switches T40 through T4n may be positioned in a region or area of the semiconductor substrate having the same conductivity type as that of an area in which the memory cells MC are located. For example, if the memory cells MC are located in a first conductivity type area 40, the bit line selection switches T40 through T4n may also be located in the first conductivity type area 40. In various embodiments, the bit line selection switches T40 through T4n may comprise, for example, a PMOS transistor, an NMOS transistor, or a CMOS transistor, or another suitable switch device.

A controller 60 may decode an address Addr received from an external source during a program operation and select a block corresponding to the decoded address Addr. The controller 60 may decode a row address and a column address in the address Addr and selectively activate or deactivate the selection lines SL0 through SLm and the bit line selection switch lines SSG0 through SSGn based on the decoded row and column addresses. To perform the above operation, the controller 60 may include an X decoder and a Y decoder and may further include a command decoder.

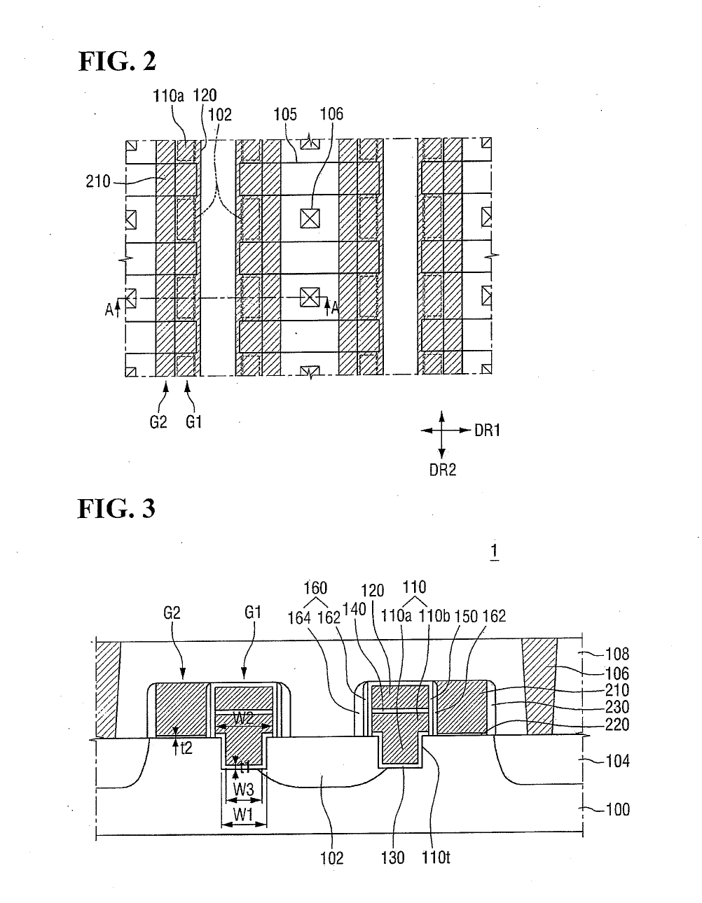

A nonvolatile memory device according to an embodiment of the present inventive concepts will now be described with reference to FIGS. 2 and 3.

FIG. 2 is a layout view of a nonvolatile memory device 1 according to an embodiment of the present inventive concepts. FIG. 3 is a cross-sectional view of the nonvolatile memory device 1 shown in FIG. 2. Specifically, FIG. 3 is a cross-sectional view taken along the axis A-A of FIG. 2.

Referring to FIG. 2, a plurality of device isolation layers 105 are formed in a substrate 100 to extend in a first direction DR1. The device isolation layers 105 define active regions. The device isolation layers 105 may be arranged in a matrix.

A first impurity region 102 is formed between the device isolation layers 105 arranged in a second direction DR2. The first impurity region 102 extends in the second direction DR2.

A width of the first impurity region 102 may be greater than a width of a space between the device isolation layers 105 which are adjacent to each other in the first direction DR1. A second impurity region 104 is formed between side surfaces of the device isolation layers 105 which extend in the first direction DR1.

A first gate pattern G1 and a second gate pattern G2 extend in the second direction DR2. That is, the first gate pattern G1 and the second gate pattern G2 extend in a direction different from the direction in which the device isolation layers 105 extend. Pairs of the first gate pattern G1 and the second gate pattern G2 are formed respectively at the ends of the device isolation layers 105. The first gate pattern G1 and the second gate pattern G2 are formed adjacent to each other. The first gate pattern G1 is formed to interface with the first impurity region 102, and the second gate pattern G2 is formed to interface with the second impurity region 104. The first gate pattern G1 corresponds to the memory transistor T1 of FIG. 1, and the second gate pattern G2 corresponds to the selection transistor T2 of FIG. 1.

A conductive plug 106 is formed on the second impurity region 104 and is electrically connected to the second impurity region 104.

Referring to FIG. 3, the nonvolatile memory device 1 includes the first gate pattern G1, the second gate pattern G2, and the first impurity region 102.

The substrate 100 includes a first trench 110t formed therein. In the example embodiment of FIG. 3, the first trench 110t is depicted as being generally box-shaped. However, the shape of the first trench 110t is not limited to the box shape. That is, the first trench 110t can have any shape that includes edges, rounded edges, or sharp tips to result in the concentration of an electric field. The first trench 110t may have a first width w1. In a case where the first trench 110t has sloping, or tapered, side surfaces, the width of the first trench 110t may be defined as a width of a widest portion of the first trench 110t. The substrate 100 comprise any of a number of suitable substrate materials and forms, e.g., a bulk silicon substrate or a silicon-on-insulator (SOI) substrate. Alternatively, the substrate 100 may comprise a silicon substrate or a substrate made of another material such as silicon germanium, indium antimonide, lead telluride, indium arsenide, indium phosphide, gallium arsenide, or gallium antimonide. However, the material that forms the substrate 100 is not limited to the above example materials. In a method of fabricating a semiconductor device according to the present inventive concepts, for the purpose of the description of the illustrative embodiment, it will be assumed that the substrate 100 is a silicon substrate.

The first gate pattern G1 is formed in a region where the first trench 110t is formed. The first gate pattern G1 includes a first bottom gate electrode 110, a first top gate electrode 120, a first gate insulating layer 130, and an inter-gate insulating layer 140.

The first bottom gate electrode 110 includes a first portion 110a formed in the first trench 110t and a second portion 110b formed on the substrate 100. That is, the first portion 110a of the first bottom gate electrode 110 is buried in the substrate 100, and the second portion 110b of the first bottom gate electrode 110 protrudes in an upward direction relative to the substrate 100. The first bottom gate electrode 110 may comprise polysilicon, or other suitable gate material; however, embodiments are not limited thereto.

The second portion 110b of the first bottom gate electrode 110 may have a second width w2, and the first portion 110a of the first bottom gate electrode 110 may have a third width w3. In the nonvolatile memory device 1 according to the current embodiment, the second portion 110b of the first bottom gate electrode 110 is wider than the width W1 of the first trench 110t. The first trench 110t, which is narrower than the second portion 110b of the first bottom gate electrode 110, may be entirely overlapped by, or covered by, the second portion 110b of the first bottom gate electrode 110.

Since the first portion 110a of the first bottom gate electrode 110 is formed to extend into the first trench 110t, it is narrower than the second portion 110b of the first bottom gate electrode 110. Thus, the first portion 110a of the first bottom gate electrode 110 may be entirely overlapped by the second portion 110b of the first bottom gate electrode 110.

In the nonvolatile memory device 1 according to the current embodiment, the first bottom gate electrode 110 may comprise a floating gate which is suitable for storing electrons.

The first gate insulating layer 130 is interposed between the inner sidewalls and bottom of the first trench 110t and the first bottom gate electrode 110. In some embodiments, the first gate insulating layer 130 is formed between the first trench 110t and the first portion 110a of the first bottom gate electrode 110 and between the substrate 100 and the second portion 110b of the first bottom gate electrode 110. That is, since the first trench 110t is narrower than the second portion 110b of the first bottom gate electrode 110, a portion of the first gate insulating layer 130 is formed between the substrate 100 and the second portion 110b of the first bottom gate electrode 110.

The first gate insulating layer 130 may have a first thickness t1 and may be conformally formed in the first trench 110t. The first gate insulating layer 130 may comprise, for example, silicon oxide. The first gate insulating layer 130 included in the first gate pattern G1 may be a tunnel oxide through which electrons previously stored or to be stored in the first bottom gate electrode 110 are permitted to pass.

The first top gate electrode 120 is formed on the first bottom gate electrode 110. The first top gate electrode 120 may comprise polysilicon; however, embodiments are not thereby limited.

In the nonvolatile memory device 1 according to the current embodiment, the first top gate electrode 120 may comprise a control gate which controls the first gate pattern G1.

The inter-electrode insulating layer 140 is interposed between the first top gate electrode 120 and the first bottom gate electrode 110. That is, the inter-electrode insulating layer 140 is formed on the second portion 110b of the first bottom gate electrode 110. The inter-electrode insulating layer 140 prevents electrons that are present in the first bottom gate electrode 110 from flowing into the first top gate electrode 120.

In some embodiments, the inter-electrode insulating layer 140 may comprise a structure in which, e.g., oxide, nitride, and oxide are stacked sequentially. That is, the inter-electrode insulating layer 140 may have an oxide-nitride-oxide (ONO) structure.

A blocking insulating layer 150 may cover exterior top and sidewall portions of the electrode structure 110, 120 and 140 of the first gate pattern G1. That is, the blocking insulating layer 150 surrounds exterior portions of the second portion 110b of the first bottom gate electrode 110 which protrudes in an upward direction relative to the substrate 100, exterior portions of the inter-electrode insulating layer 140, and exterior portions of the first top gate electrode 120. The blocking insulating layer 150 may electrically insulate the electrode structure 110, 120 and 140 of the first gate pattern G1 from the outside. The blocking insulating layer 150 may conformally cover the outside of the electrode structure 110, 120 and 140 of the first gate pattern G1. The blocking insulating layer 150 may comprise, for example, oxide, or other suitable insulative material.

The second gate pattern G2 may be positioned on the substrate 100 at a location that is adjacent a side of the first gate pattern G1. In some embodiments, the second gate pattern G2 includes a second gate insulating layer 220 and a second gate electrode 210.

The second gate electrode 210 is insulated from the first gate pattern G1. As described herein, the exterior of the first gate pattern G1 is surrounded by the blocking insulating layer 150. Since the second gate pattern G2 is insulated from the first gate pattern G1, a threshold voltage of the second gate pattern G2 is controlled independently of a threshold voltage of the first gate pattern G1.

Since the second gate electrode 210 is formed adjacent to the first gate pattern G1, it does not overlap, in a vertical direction, the first top gate electrode 120 and the first bottom gate electrode 110.

The second gate electrode 210 may comprise, for example, silicon or metal. Specifically, the second gate electrode 210 may include one of polycrystalline silicon (poly-Si), amorphous silicon (a-Si), titanium (Ti), titanium nitride (TiN), tantalum nitride (TaN), aluminum (Al), and a combination of the same, or other suitable gate structure materials.

In the nonvolatile memory device 1 according to the embodiments, the first bottom gate electrode 110, the first top gate electrode 120 and the second gate electrode 210 included in the first gate pattern G1 and the second gate pattern G2 may include polysilicon. That is, the first gate pattern G1 and the second gate pattern G2 may take the form of a 3-poly split gate structure.

The second gate insulating layer 220 is interposed between the substrate 100 and the second gate electrode 210. Unlike the first gate insulating layer 130 which is positioned on the sidewalls and lower surface of the trench, the second gate insulating layer 220 is formed on an upper surface of the substrate 100. The second gate insulating layer 220 may be a silicon oxide layer, SiON, GexOyNz, GexSiyOz, a high-k dielectric layer, a combination of these materials, or a sequential stack of these materials. The high-k dielectric layer may comprise one or more of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate; however, embodiments are not thereby limited.

In the nonvolatile memory device 1 according to the present embodiment, the first gate insulating layer 130 and the second gate insulating layer 220 may include silicon oxide. The second gate insulating layer 220 may have a second thickness t2, and the thickness t2 of the second gate insulating layer 220 may be different from the thickness t1 of the first gate insulating layer 130. For example, in some embodiments, the thickness t1 of the first gate insulating layer 130 may be greater than the thickness t2 of the second gate insulating layer 220.

The first gate pattern G1 may further include a first spacer 160 formed on a side surface thereof. That is, the first spacer 160 may be formed on a side surface of the first gate pattern G1 which is not adjacent to the second gate pattern G2. The second gate pattern G2 may further include a second spacer 230 formed on a side surface thereof. That is, the second spacer 230 may be formed on a side surface of the second gate pattern G2 which is not adjacent to the first gate pattern G1. An inter-pattern spacer 162 may be formed between the first gate pattern G1 and the second gate pattern G2. The inter-pattern spacer 162 may further operate to electrically insulate the first gate pattern G1 and the second gate pattern G2 from each other, together with the blocking insulating layer 150.

The first spacer 160, the second spacer 230, and the inter-pattern spacer 162 may comprise, e.g., a silicon nitride layer, a silicon oxynitride layer, a silicon oxide layer, or a silicon carbon nitride (SiOCN) layer, or other suitable insulative layer. In the illustration of FIG. 3, each of the second spacer 230 and the inter-pattern spacer 162 is shown as being a single layer. However, the present inventive concepts is not limited thereto, and each of the second spacer 230 and the inter-pattern spacer 162 can be formed as a multilayer.

A portion 162 of the first spacer 160 which is closer to the blocking insulating layer 150 may be formed at the same level of the inter-pattern spacer 162. A portion 164 of the first spacer 160 which is further away from the blocking insulating layer 150 may be formed at the same level as the second spacer 230. Here, if elements are referred to as being formed at the same level, this means that the elements are formed during the same fabrication process.

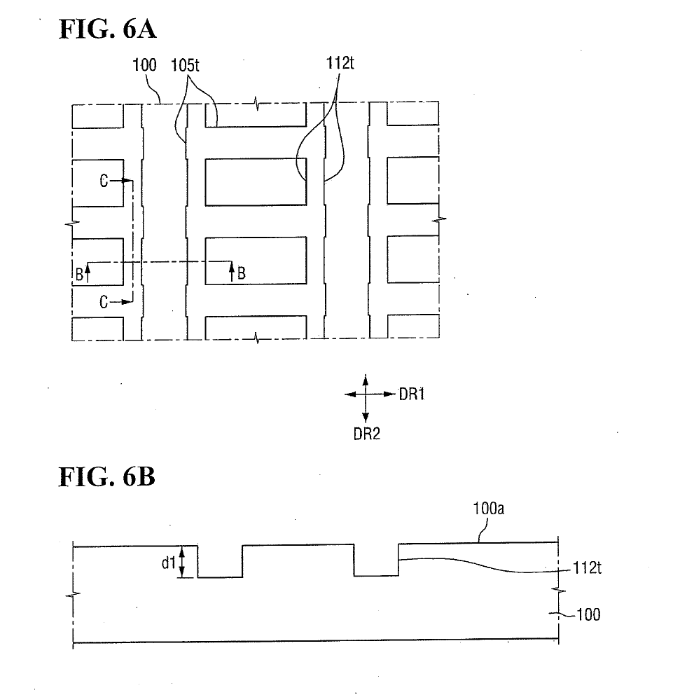

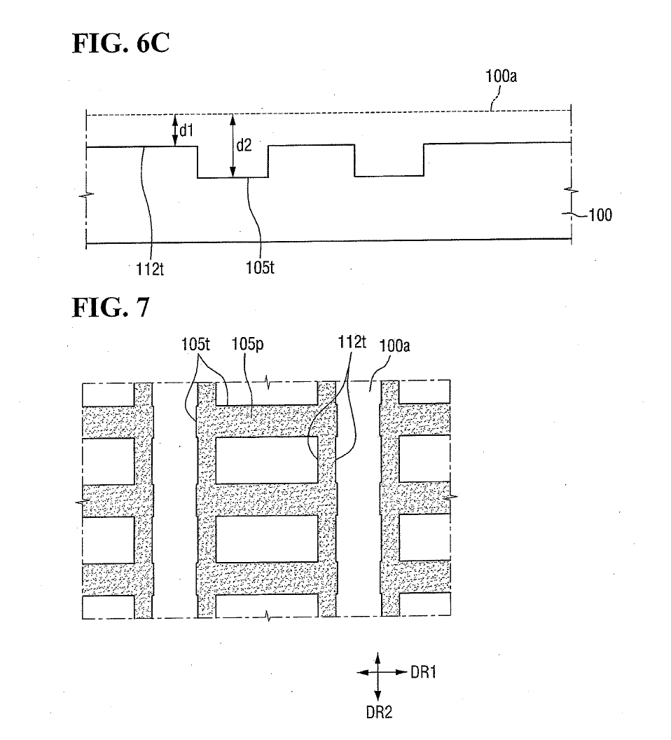

In the nonvolatile memory device 1 according to the embodiment depicted in FIG. 3, the first spacer 160 may be wider than the inter-pattern spacer 162. Referring to a method of fabricating a nonvolatile memory device which will be described herein with reference to FIGS. 6 through 14, a width of the first spacer 160 may be substantially equal to the sum of a width of the second spacer 230 and a width of the inter-pattern spacer 162.

Referring to FIGS. 2 and 3, the first impurity region 102 is formed at a side of the first gate pattern G1 which is opposite the corresponding second gate pattern G2. That is, the first impurity region 102 is formed on a side of the first gate pattern G1 which is not adjacent to the second gate pattern G2. In some embodiments, the first impurity region 102 may be a source/drain connected commonly to neighboring first gate patterns G1, and thus is shared by the neighboring first gate patterns G1.

The first impurity region 102 may overlap part of the first trench 110t. Specifically, the first impurity region 102 may partially be positioned below a bottom surface of the first trench 110t, for example, as shown in FIG. 3. In this example embodiment, the first impurity region 102 covers part of the bottom surface of the first trench 110t and a side surface of the first trench 110t. The first impurity region 102 covers a side surface of the first trench 110t which is opposite the position of the second gate pattern G2. As shown in the embodiment of FIG. 3, the first impurity region 102 can be configured to cover an entire edge of the first trench 110t.

In the nonvolatile memory device 1 according to the current embodiment, part of the first portion 110a of the first bottom gate electrode 110 which formed in the first trench 110t may overlap, in a vertical direction, at least a portion of the first impurity region 102.

In some embodiments, a bottom surface of the first impurity region 102 is lower in position than the bottom surface of the first trench 110t.

Since the first impurity region 102 covers part of the bottom surface of the first trench 110t and a side surface of the first trench 110t, electrons stored in the first bottom gate electrode 110 can be removed effectively. If a voltage difference occurs between the first bottom gate electrode 110 and the first impurity region 102, an electric field is concentrated at edge portions of the first trench 110t. The concentration of the electric field causes electrons stored in the first bottom gate electrode 110 to readily escape into the first impurity region 102.

In addition, since part of the first bottom gate electrode 110 is buried in the substrate 100, a channel length of the first gate pattern G1 is relatively greater as compared to a configuration whereby the first bottom gate electrode 110 is formed flat on the substrate 100. As a result, the configuration of the first gate pattern is conductive to further integration, while maintaining the channel length of the first gate pattern, while minimizing susceptibility to the short channel effect.

Further, of the electrons that pass through a channel of the second gate pattern G2, certain electrons, referred to ballistic electrons, may penetrate a side surface of the first trench 110t to be stored in the first bottom gate electrode 110.

In some embodiments, a nonvolatile memory device 1 further includes the second impurity region 104 formed on a side of the second gate pattern G2 which is opposite a side of the first gate pattern G1. The second impurity region 104 may comprise a source/drain connected commonly to adjacent second gate patterns G2.

The conductive plug 106 is disposed on the second impurity region 104 and formed in an interlayer insulating film 108 which covers the first gate pattern G1 and the second gate pattern G2.

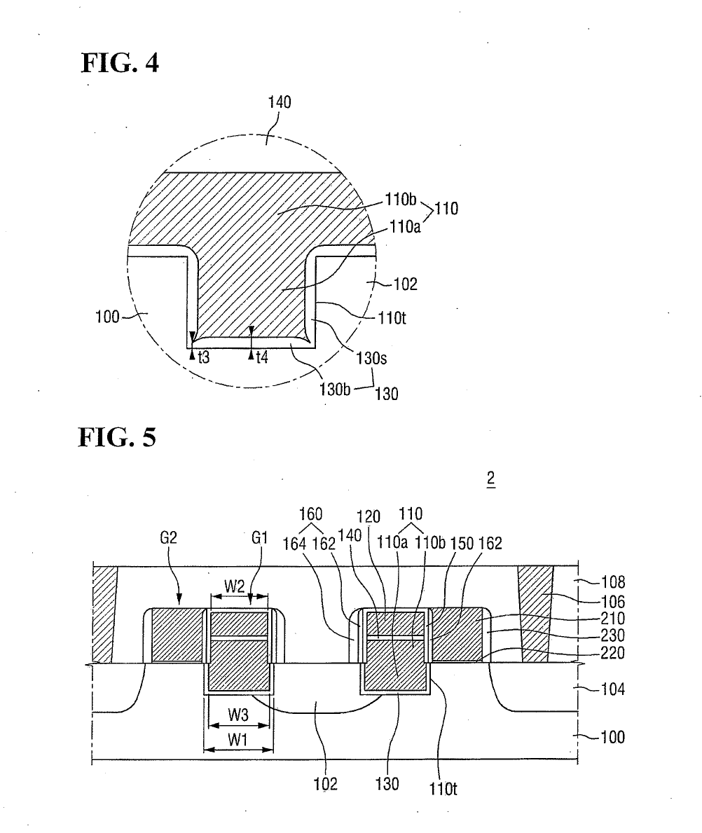

A modified example of the nonvolatile memory device 1 according to the embodiment of FIGS. 2 and 3 will now be described with reference to FIG. 4. The modified example is substantially identical to the embodiment of FIGS. 2 and 3 except in the thickness of a first gate insulating layer 130 varies, since the layer 130 is not conformal. Therefore, the following description will focus on differences between the embodiment of FIG. 4 and the embodiment of FIGS. 2 and 3.

FIG. 4 is a cross-sectional view of a modified example of the nonvolatile memory device 1 according to the embodiment of FIGS. 2 and 3. Specifically, FIG. 4 is a partial enlarged view of a first bottom gate electrode 110 of a first gate pattern G1.

Referring to FIG. 4, the first gate insulating layer 130 includes a first bottom gate insulating layer 130b and a first side gate insulating layer 130s. The first bottom gate insulating layer 130b is formed on a bottom surface of a first trench 110t, and the first side gate insulating layer 130s is formed on side surfaces of the first trench 110t.

A thickness of the first bottom gate insulating layer 130b formed on the bottom surface of the first trench 110t varies and is not uniform. That is, the first bottom gate insulating layer 130b has a third thickness t3 in regions proximal to edges of the first trench 110t. The first bottom gate insulating layer 130b has a fourth thickness t4, which is different from the third thickness t3, in central regions of the bottom surface of the first trench 110t. The thickness t4 of the first bottom gate insulating layer 130b in regions near the center of the bottom surface of the first trench 110t is greater than the thickness t3 of the first bottom gate insulating layer 130b in regions near the edges of the first trench 110t.

The thickness t3 of the first bottom gate insulating layer 130b may be least in regions at which the bottom surface of the first trench 110t meets a side surface thereof. That is, the first bottom gate insulating layer 130b may be thinnest at each location where the first bottom gate insulating layer 130b meets the first side gate insulating layer 130s.

A nonvolatile memory device according to another embodiment of the present inventive concepts will now be described with reference to FIG. 5. Elements identical to those of the embodiment described above with reference to FIG. 3 are indicated by like reference numerals, and any repetitive detailed description thereof will be simplified or omitted.

FIG. 5 is a cross-sectional view of a nonvolatile memory device 2 according to another embodiment of the present inventive concepts.

Referring to FIG. 5, the nonvolatile memory device 2 includes a first gate pattern G1, a second gate pattern G2, and a first impurity region 102.

The first gate pattern G1 includes a first bottom gate electrode 110, a first top gate electrode 120, and a first spacer 160. The first bottom gate electrode 110 includes a first portion 110a which is formed in a first trench 110t formed in a substrate 100 and a second portion 110b which protrudes in an upward direction relative to the substrate 100.

The first gate pattern G1 further includes a blocking insulating layer 150 which surrounds the exterior sidewall portions of the first gate pattern G1. The blocking insulating layer 150 is formed on the substrate 100 and surrounds the outside of the second portion 110b of the first bottom gate electrode 110 which protrudes in an upward direction from the substrate 100 and the outside of the first top gate electrode 120.

The first spacer 160 is formed on a side surface of the first gate pattern G1 which protrudes upward from the substrate 100. The first spacer 160 is formed on a side surface of the first gate pattern G1 which is not adjacent to the second gate pattern G2. That is, the first spacer 160 may be formed adjacent to the first impurity region 102 which is formed at a side of the first gate pattern G1 and may overlap the first impurity region 102.

In the nonvolatile memory device 2 according to the present embodiment, the first trench 110t may be overlapped by a portion of the first spacer 160.

Specifically, the first trench 110t has a first width w1, the second portion 110b of the first bottom gate electrode 110 has a second width w2, and the first portion 110a of the first bottom gate electrode 110 has a third width w3. The width w1 of the first trench 110t is greater than the width w2 of the second portion 110b of the first bottom gate electrode 110. Accordingly, the entire body of the second portion 110b of the first bottom gate electrode 110 may overlap the first trench 110t. Since the width w1 of the first trench 110t is greater than the width w2 of the second portion 110b of the first bottom gate electrode 110, a portion of the first trench 110t is not overlapped by the second portion 110b of the first bottom gate electrode 110 and the first top gate electrode 120. The portion of the first trench 110t which is not overlapped by the first top gate electrode 120 may be at least partially overlapped by the blocking insulating layer 150 which surrounds the exterior sidewalls of the first top gate electrode 120. Alternatively, the portion of the first trench 110t which is not overlapped by the first top gate electrode 120 may be overlapped by the blocking insulating layer 150 and a portion of the first spacer 160.

That is, in FIG. 5, the first trench 110t is depicted as being partially overlapped by a portion of the first spacer 160 and the blocking insulating layer 150. However, depending on the geometries of the various components and layers, in some embodiments, the first trench 110t may be partially overlapped by the blocking insulating layer 150 but not overlapped by the first spacer 160.

In addition, the first trench 110t may be overlapped by a portion of an inter-pattern spacer 162 formed between the first gate pattern G1 and the second gate pattern G2.

As described above with reference to FIG. 3, the first spacer 160 may be wider than the inter-pattern spacer 162. Therefore, if the whole of the inter-pattern spacer 162 overlaps the first trench 110t, a portion of the first trench 110t may be overlapped by a second gate electrode 210.

In the example embodiment of FIG. 5, the width w3 of the first portion 110a of the first bottom gate electrode 110 is greater than the width w2 of the second portion 110b of the first bottom gate electrode 110, and the whole of the second portion 110b of the first bottom gate electrode 110 overlaps the first portion 110a of the first bottom gate electrode 110. However, this is merely an example used for ease of description, and the present inventive concepts are not limited to this example. That is, in some embodiments, the width w3 of the first portion 110a of the first bottom gate electrode 110 may be equal to or smaller than the width w2 of the second portion 110b of the first bottom gate electrode 110.

A method of fabricating a nonvolatile memory device according to an embodiment of the present inventive concepts will now be described with reference to FIGS. 2, 3 and 6A through 14.

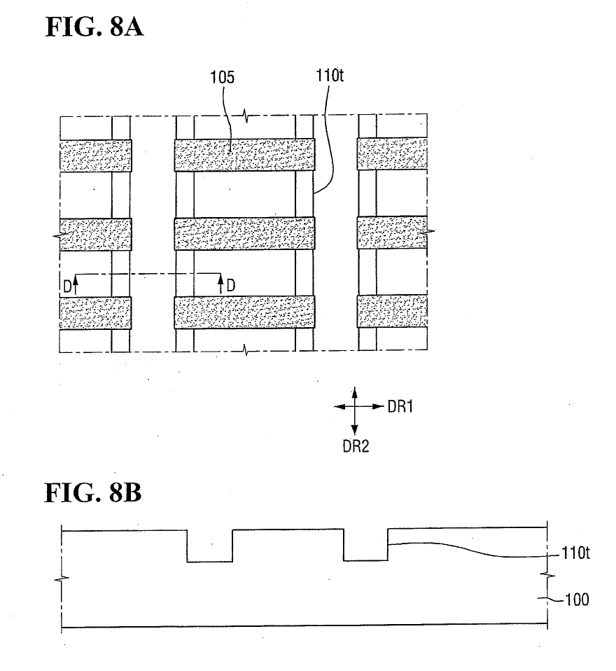

FIGS. 6A through 14 are views illustrating intermediate processes included in a method of fabricating a nonvolatile memory device according to an embodiment of the present inventive concepts. FIGS. 6B and 6C are cross-sectional views as seen along directions B-B and C-C of FIG. 6A, respectively. FIG. 8B is a cross-sectional view as seen along direction D-D of FIG. 8A.

Referring to FIG. 6A, a plurality of second trenches 105t are formed in a substrate 100 to extend in a first direction DR1. A first pre-trench 112t is formed in the substrate 100 to extend in a second direction DR2 and overlap part of each of the second trenches 105t.

Specifically, each of the second trenches 105t is shaped in the form of a rectangle extending in the first direction DR1. That is, each of the second trenches 105t may have long sides extending in the first direction DR1 and short sides extending in the second direction DR2. The long sides of the second trenches 105t are arranged adjacent to each other in the second direction DR2. The second trenches 105t may be separated by a predetermined distance in each of the first direction DR1 and the second direction DR2.

The first pre-trench 112t extends in the second direction DR2 and overlaps part of each of the second trenches 105t. The first pre-trench 112t may overlap both end portions of each of the second trenches 105t. The first pre-trench 112t may overlap part of each of the second trenches 105t arranged at regular intervals along the second direction DR2.

In the drawing, each end of each of the second trenches 105t which intersect the first pre-trench 112t partially protrudes from a side of the first pre-trench 112t extending in the second direction DR2. However, the present inventive concepts is not limited thereto.

The second trenches 105t arranged in the second direction DR2 and the first pre-trench 112t overlapping both end portions of each of the second trenches 105t may generally form the shape of a ladder.

Referring to FIGS. 6B and 6C, the first pre-trench 112t is formed in the substrate 100. The first pre-trench 112t may have a first depth d1. The second trenches 105t are formed in the substrate 100 to partially overlap the first pre-trench 112t. Each of the second trenches 105t has a second depth d2.

In a subsequent process, a device isolation layer is formed in each of the second trenches 105t, and the first pre-trench 112t becomes a first trench 110t. Therefore, the depth d2 of each of the second trenches 105t is greater than the depth d1 of the first pre-trench 112t. That is, a distance from a top surface 100a of the substrate 100 to a bottom surface of each of the second trenches 105t is greater than a distance from the top surface 100a of the substrate 100 to a bottom surface of the first pre-trench 112t.

Referring to FIG. 7, an insulating layer 105p is formed to fill the first pre-trench 112t and the second trenches 105t formed in the substrate 100. That is, the insulating layer 105p is formed in the first pre-trench 112t and the second trenches 105t. The insulating layer 105p may be formed by forming an insulating material on the substrate 100 to fill the first pre-trench 112t and the second trenches 105t and then planarizing the insulating material until the top surface 100a of the substrate 100 is exposed.

The insulating layer 105p may be formed of an oxide layer. Although there may be some differences according to design rules of a semiconductor device, in some embodiments, the insulating layer 105p may be stacked by ozone-tetra ortho silicate glass (TEOS), atmospheric pressure chemical vapor deposition (APCVD), plasma enhanced chemical vapor deposition (PECVD), or by high density plasma chemical vapor deposition (HDP CVD).

Referring to FIGS. 8A and 8B, of the insulating layer 105p formed in the first pre-trench 112t and the second trenches 105t, a portion of the insulating layer that is formed in a portion of the first pre-trench 112t which does not overlap the second trenches 105t is removed.

Specifically, a mask pattern is formed to expose the insulating layer 105p formed in a portion of the first pre-trench 112t which does not overlap the second trenches 105t. After the formation of the mask pattern, the insulating layer 105p formed in the portion of the first pre-trench 112t which does not overlap the second trenches 105t is removed by an etching process. In various embodiments, the etching process may include one of dry etching and wet etching.

As a result of the etching process, the insulating layer 105p remains only in the second trenches 105t and the insulating layer 105p is removed from the portion of the first pre-trench 112t which does not overlap the second trenches 105t. Accordingly, the insulating layer 105p formed in each of the second trenches 105t becomes a device isolation layer 105. In addition, the removal of the insulating layer 105p from the portion of the first pre-trench 112t which does not overlap the second trenches 105t exposes the substrate 100, resulting in the formation of the first trench 110t in the substrate 100.

A subsequent fabrication process will be described with reference to FIGS. 8B-14 which is a cross-sectional view taken along line D-D of FIG. 8A.

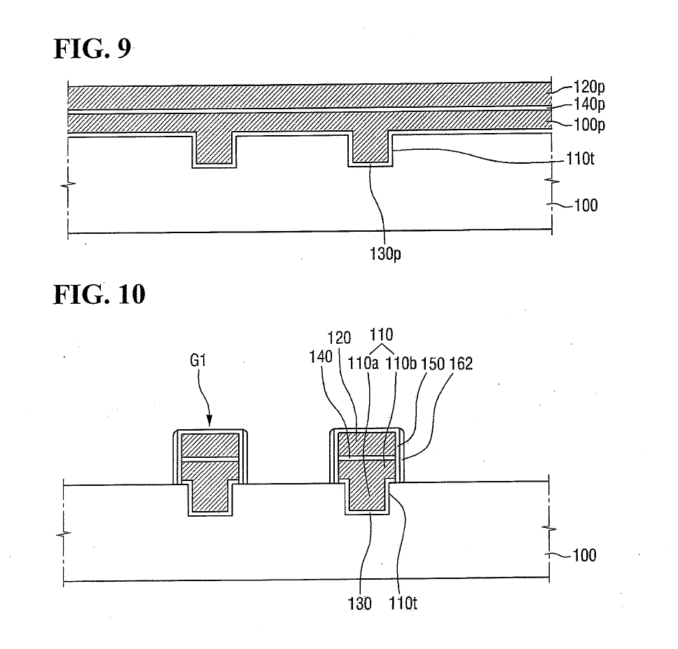

Referring to FIG. 9, a first pre-gate insulating layer 130p is formed to cover the first trench 110t and the substrate 100. Then, a first bottom gate electrode layer 100p is formed on the first pre-gate insulating layer 130p to fill the first trench 110t. A portion of the first bottom gate electrode layer 100p fills the first trench 110t, and the other portion of the first bottom gate electrode layer 100p is formed on the substrate 100. A pre-inter-electrode insulating layer 140p and a first top gate electrode layer 120p are formed sequentially on the first bottom gate electrode layer 100p.

Specifically, the first pre-gate insulating layer 130p is formed on the first trench 110t and the exposed substrate 100. The first pre-gate insulating layer 130p may comprise, for example, an oxide layer. The first pre-gate insulting layer 130p may be &Lined by, for example, thermal oxidation, chemical vapor deposition (CVD), or atomic layer deposition (ALD). When ALD is used to form the first pre-gate insulating layer 130p, the first pre-gate insulating layer 130p may be formed by thermal oxidation of the substrate 100 in an oxygen atmosphere or by rapid thermal oxidation of the substrate 100 at a temperature ranging from approximately 700 to 1100° C. The oxygen atmosphere may be created by injecting H₂O₂, O₃, or H₂O. When ALD is used to form the first pre-gate insulating layer 130p, a densification process may further be performed after or while the first pre-gate insulating layer 130p is formed on the substrate 100 and in the first trench 110t. The densification process may operate to increase the density of the first pre-gate insulating layer 130p, thereby reducing leakage current in the resulting device.

Next, the first bottom gate electrode layer 100p is formed to fill the first trench 110t and, at the same time, cover the substrate 100. The first bottom gate electrode layer 100p may include, for example, polysilicon. To make a top surface of the first bottom gate electrode layer 100p flat, the first bottom gate electrode layer 100p may be planarized.

The pre-inter-electrode insulating layer 140p is formed on the planarized first bottom gate electrode layer 100p. In some embodiments, the pre-inter-electrode insulating layer 140p may include an oxide-nitride-oxide stacked structure. Therefore, after an oxide is formed on the first bottom gate electrode layer 100p, a nitride may be formed on the oxide, and then the oxide may be formed again on the nitride. The result is the pre-inter-electrode insulating layer 140p.

The first top gate electrode layer 120p is formed on the pre-inter-electrode insulating layer 140p. The first top gate electrode layer 120p may comprise, for example, polysilicon.

Referring to FIG. 10, a first gate stack structure 110, 120, 130 and 140 may be formed by patterning the first pre-gate insulating layer 130p, the first bottom gate electrode layer 100p, the pre-inter-electrode insulating layer 140p, and the first top gate electrode layer 120p stacked sequentially. A first gate pattern G1 is formed by covering external portions of the first gate stack structure 110, 120, 130 and 140 with a blocking insulating layer 150. Then, an inter-pattern spacer 162 is formed on side surfaces of the first gate pattern G1.

Specifically, like the first gate pattern G1 of FIG. 2, the first gate stack structure 110, 120, 130 and 140 extending in the second direction DR2 is formed by patterning the first pre-gate insulating layer 130p, the first bottom gate electrode layer 100p, the pre-inter-electrode insulating layer 140p, and the first top gate electrode layer 120p stacked sequentially on the substrate 100. In addition, like the first gate pattern G1 of FIG. 2, the first gate stack structure 110, 120, 130 and 140 is formed in pairs. That is, pairs of the first gate stack structures 110, 120, 130 and 140 are formed on corresponding pairs of the first trenches 110t.

Next, the blocking insulating layer 150 is formed on the substrate 100 to surround external surfaces of the first gate stack structure 110,120, 130 and 140, thereby completing the first gate pattern G1. That is, the blocking insulating layer 150 surrounds the outside of the first bottom gate electrode 110 which protrudes in an upward direction from the substrate 100 and the outside of the first top gate electrode 120. The blocking insulating layer 150 may comprise, e.g., oxide and may be formed by CVD, thermal oxidation, or ALD.

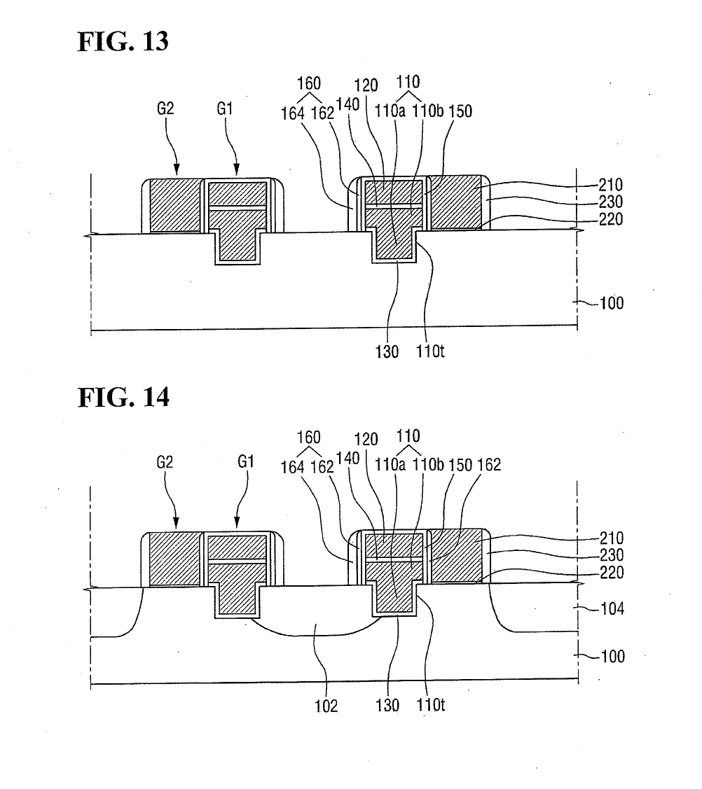

Next, the inter-pattern spacer 162 is formed on side surfaces of the first gate pattern G1 having the blocking insulating layer 150. The inter-pattern spacer 162 formed on a side of the first gate pattern G1 will be made to come in contact with a second gate pattern G2 formed in a later process, and the inter-pattern spacer 162 on the other side of the first gate pattern G1 becomes part of a first sidewall spacer 160, as described below in connection with FIG. 13.

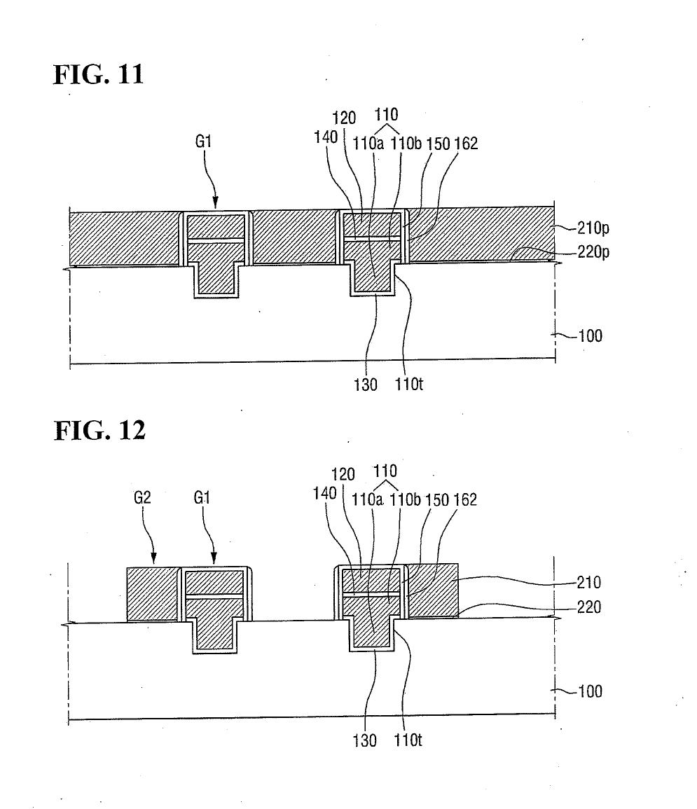

Referring to FIG. 11, a second pre-gate insulating layer 220p and a second gate electrode layer 210p are formed on both sides of the first gate pattern G1 formed in pairs. The second pre-gate insulating layer 220p and the second gate electrode layer 210p are formed adjacent to the first gate pattern G1 and are stacked sequentially on the substrate 100. That is, the second pre-gate insulating layer 220p and the second gate electrode layer 210p are sequentially formed on the exposed substrate 100.

Referring to FIG. 12, the second pre-gate insulating layer 220p and the second gate electrode layer 210p are sequentially formed on a portion of the substrate 100 which is not covered with the first gate pattern G1 extending in the second direction DR2. In some embodiments, after the second gate electrode layer 210p is formed adjacent to both sides of the first gate pattern G1, which is formed in pairs, so as to cover the first gate pattern G1 and the substrate 100, it is planarized to lie in the same plane with the first gate pattern G1.

The second pre-gate insulating layer 220p may comprise a silicon oxide layer, SiON, GexOyNz, GexSiyOz, a high-k dielectric layer, or a combination of these materials. The second gate electrode layer 210p may include, e.g., polysilicon or metal.

Referring to FIG. 12, the second gate pattern G2 is formed at a side of the first gate pattern G1 by patterning the second pre-gate insulating layer 220p and the second gate electrode layer 210p stacked sequentially. In addition, the second pre-gate insulating layer 220p and the second gate electrode layer 210p formed on the other side of the first gate pattern G1 are removed. In other words, portions of the second pre-gate insulating layer 220p and the second gate electrode layer 210p formed between a pair of the first gate patterns G1 are removed, thereby exposing the substrate 100. On the other hand, the second pre-gate insulating layer 220p and the second gate electrode layer 210p outside regions between the pair of the first gate patterns G1 are removed, except for their portion adjacent to each of the pair of the first gate patterns G1. As a result, the second gate pattern G2 is formed.

In some embodiments, each two pairs of the first gate pattern G1 and the second gate pattern G2 are symmetrical to each other with respect to the substrate 100 exposed between the first gate patterns G1. In addition, each two pairs of the first gate pattern G1 and the second gate pattern G2 formed at both ends of one device isolation layer 105 are symmetrical to each other with respect to a center of the device isolation layer 105.

Referring to FIGS. 2 and 12, portions of the second gate electrode layer 210p and the second pre-gate electrode layer 220p formed between a pair of the first gate patterns G1 which overlap respective ends of the device isolation layers 105 adjacent to each other in the first direction DR1 are removed to expose the substrate 100. On the other hand, only a central portion of the second gate electrode layer 210p and the second pre-gate insulating layer 220p formed between a pair of the first gate patterns G1 which overlap both ends of one device isolation layer 105 is removed to expose the substrate 100, while a portion of the second gate electrode layer 210p which is adjacent to each of the pair of the first gate patterns G1 is not removed. Accordingly, the second gate pattern G2 is formed to be adjacent to each of the pair of the first gate patterns G1 and extend in the second direction DR2.

Referring to FIG. 13, a spacer 164 is formed at a side surface of the first gate pattern G1 opposite the second gate pattern G2. Accordingly, the first spacer 160 is formed on the side surface of the first gate pattern G1 which is not adjacent to the second gate pattern G2. In addition, a second spacer 230 is formed at a side surface of the second gate pattern G2 which is opposite to the first gate pattern G1.

Referring to FIG. 14, a first impurity region 102 is formed by injecting impurities between a pair of neighboring ones of the first gate patterns G1. A second impurity region 104 is formed by injecting impurities at a side of the second gate pattern G2. The first impurity region 102 is formed at a side of each of the first gate patterns G1, which is not adjacent to the second gate pattern G2, and covers part of the bottom surface of the first trench 110t and a side surface of the first trench 110t. A side of each of the first gate patterns G1 on which the first impurity region 102 is formed is opposite the other side thereof which is adjacent to the second gate pattern G2.

Specifically, impurities are injected into the substrate 100 at respective sides of a pair of the first gate patterns G1 which face each other. The impurities are injected at a side of each of the first gate patterns G1 which is opposite the second gate pattern G2. The type of impurities injected may vary according to the type of the first gate patterns G1 and the second gate pattern G2. For example, assuming electric charge moving through a channel region of the second gate pattern G2 are electrons, the impurities may be n-type impurities. After the injection of the impurities into the substrate 100, the substrate 100 is heat-treated. The heat treatment of the substrate 100 causes the impurities injected into the substrate 100 to diffuse. Thus, the first impurity region 102 is formed at the side of each of the pair of the facing first gate patterns G1 which is not adjacent to the second gate pattern G2.

Referring to FIGS. 2 and 14, the first impurity region 102 is formed between a pair of the first gate patterns G1 extending in the second direction DR2. That is, the first impurity region 102 does not contact the second gate pattern G2. The second impurity region 104 is formed between the second gate pattern G2 and the device isolation layers 105 arranged in the second direction DR2. That is, the second impurity region 104 does not contact the first pattern G1.

Referring to FIG. 3, an interlayer insulting film 108 is formed to cover the first gate pattern G1 and the second gate pattern G2. Then, a conductive plug 106 is formed in the interlayer insulating film 108 to be electrically connected to the second impurity region 104.

A method of fabricating a nonvolatile memory device according to another embodiment of the present inventive concepts will now be described with reference to FIGS. 2, 3, and 9 through 16. The current embodiment is substantially similar to the previous embodiment except for a method in which the first trench is formed. Therefore, elements identical to those of the previous embodiment are indicated by like reference numerals, and any repetitive detailed description thereof will be simplified or omitted.

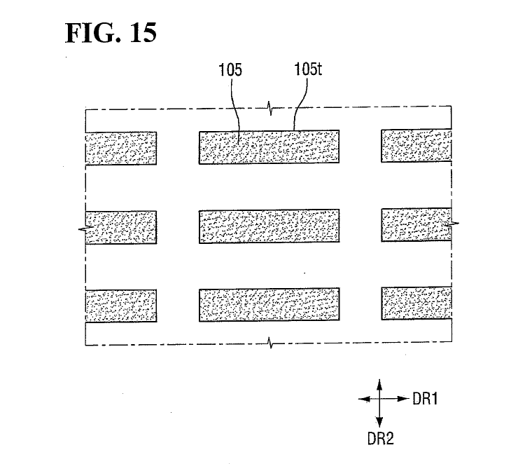

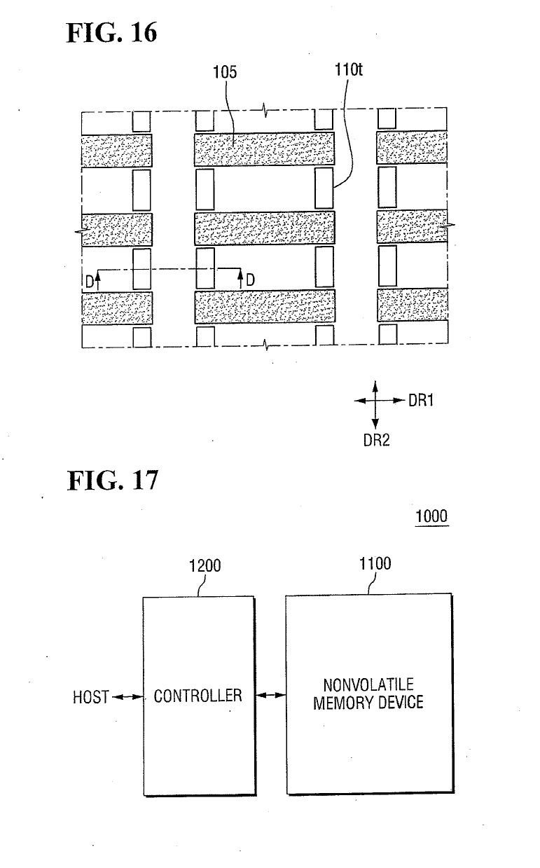

FIGS. 15 and 16 are views illustrating intermediate processes included in a method of fabricating a nonvolatile memory device according to another embodiment of the present inventive concepts.

Referring to FIG. 15, a plurality of second trenches 105t are formed in a substrate 100 to extend in a first direction DR1. Then, a plurality of device isolation layers 105 are formed by filling the second trenches 105t with an insulating material.

Specifically, each of the second trenches 105t is shaped like a rectangle extending in the first direction DR1. That is, each of the second trenches 105t may have long sides extending in the first direction DR1 and short sides extending in a second direction DR2. The long sides of the second trenches 105t are adjacent to each other in the second direction DR2. The second trenches 105t may be separated from each other by a predetermined distance in each of the first direction DR1 and the second direction DR2.

Next, an insulating material is formed on the substrate 100 to cover the substrate 100 while filling the second trenches 105t. Then, the insulating material is removed until the substrate 100 is exposed. As a result, the device isolation layers 105 are formed.

Referring to FIG. 16, a first trench 110t is formed by etching part of the substrate 100 exposed between the device isolation layers 105 arranged in the second direction DR2. The first trench 110t may be formed between the device isolation layers 105 arranged in the second direction DR2 so as to be adjacent to both ends of each of the device isolation layers 105.

In FIG. 16, part of the substrate 100 is interposed between the first trench 110t and the device isolation layers 105. However, this is merely an example used for ease of description, and the present inventive concepts is not limited to this example. That is, of two pairs of side surfaces of the first trench 110t, a pair of side surfaces may contact the substrate 100, and the other pair of side surfaces of the first trench 110t may partially contact the device isolation layers 105.

Next, a first gate pattern G1, a second gate pattern G2, and a first impurity region 102 are formed by the processes described above with reference to FIGS. 9 through 14, which will not be described again to avoid unnecessary repetition. A cross-sectional view taken along direction D-D of FIG. 16 is presented in FIG. 8B.

FIG. 17 is a block diagram of a memory system 1000 including a nonvolatile memory device according to some embodiments of the present inventive concepts.

Referring to FIG. 17, the memory system 1000 includes a nonvolatile memory device 1100 and a controller 1200.

The controller 1200 is connected to a host and the nonvolatile memory device 1100. The controller 1200 is configured to access the nonvolatile memory device 1100 in response to a request from the host. For example, the controller 1200 may be configured to control read, write, erase and background operations of the nonvolatile memory device 1100. The controller 1200 may be configured to provide an interface between the nonvolatile memory device 1100 and the host. The controller 1200 may be configured to drive firmware for controlling the nonvolatile memory device 1100.

In some embodiments, the controller 1200 further includes well-known components such as a random access memory (RAM), a processing unit, a host interface, and a memory interface. The RAM is used as at least one of an operation memory of the processing unit, a cache memory between the nonvolatile memory device 1100 and the host, and a buffer memory between the nonvolatile memory device 1100 and the host. The processing unit controls the overall operation of the controller 1200.

The host interface includes a protocol for data exchange between the host and the controller 1200. For example, the controller 1200 may be configured to communicate with an external device (e.g., the host) using at least one of various interface protocols such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, and an integrated drive electronics (IDE) protocol. The memory interface may interface with the nonvolatile memory device 1100. For example, the memory interface includes a NAND interface or a NOR interface.

The memory system 1000 may further include an error correction block. The error correction block may be configured to detect and correct errors in data read from the nonvolatile memory device 1100 using error correcting codes (ECC). For example, the error correction block may be provided as a component of the controller 1200. The error correction block can also be provided as a component of the nonvolatile memory device 1100.

The controller 1200 and the nonvolatile memory device 1100 may be integrated into one semiconductor device. Specifically, the controller 1200 and the nonvolatile memory device 1100 may be integrated into a semiconductor device to form a memory card. For example, the controller 1200 and the nonvolatile memory device 1100 may be integrated into one semiconductor device to form a personal computer (PC) card (e.g., Personal Computer Memory Card International Association (PCMCIA)), a compact flash card (CF), a smart media card (SM, SMC), a memory stick, a multimedia card (e.g., MMC, RS-MMC, MMCmicro), a SD card (e.g., SD, miniSD, microSD, SDHC), or a universal flash storage (UFS).

Alternatively, the controller 1200 and the nonvolatile memory device 1100 may be integrated into a semiconductor device to form a solid state drive (SSD). The SSD includes a storage device which stores data in a semiconductor memory. When the memory system 1000 is used as an SSD, the operation speed of the host connected to the memory system 1000 may increase significantly.

The memory system 1000 may be implemented in a computer, an ultra-mobile PC (UMPC), a workstation, a net-book, a personal digital assistant (PDA), a portable computer, a web tablet, a wireless phone, a mobile phone, a smart phone, an e-book, a portable multimedia player (PMP), a portable game device, a navigation device, a black box, a digital camera, a three-dimensional television, a digital audio recorder, a digital audio player, a digital picture recorder, a digital picture player, a digital video recorder, a digital video player, a device capable of transmitting/receiving information in wireless environments, one of various electronic devices constituting a home network, one of various electronic devices constituting a computer network, one of various electronic devices constituting a telematics network, a radio frequency identification (RFID) device, or one of various components constituting a computing system.

The nonvolatile memory device 1100 or the memory system 1000 may be packaged using various forms of packages. The nonvolatile memory device 1100 or the memory system 1000 may be packaged using packages such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline integrated circuit (SOIC), shrink small outline package (SSOP), thin small outline package (TSOP), thin quad flat pack (TQFP), system in package (SIP), multi chip package (MCP), wafer-level fabricated package (WFP), and wafer-level processed stack package (WSP).

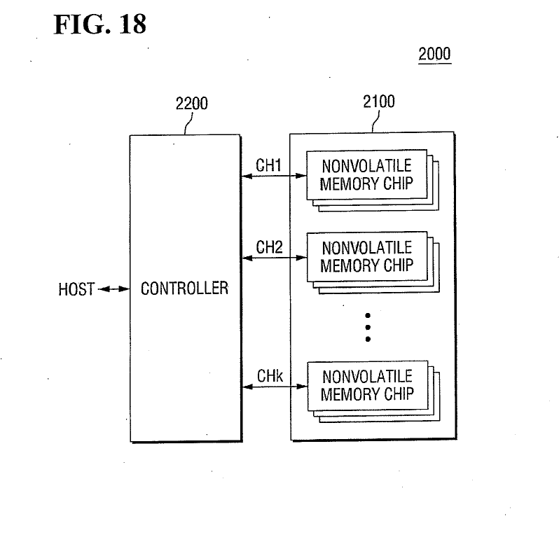

FIG. 18 is a block diagram of an application example of the memory system 1000 shown in FIG. 17.

Referring to FIG. 18, a memory system 2000 includes a nonvolatile memory device 2100 and a controller 2200. The nonvolatile memory device 2100 includes a plurality of nonvolatile memory chips. The nonvolatile memory chips form multiple memory chip groups. Each of the memory chip groups has one common channel for communication with the controller 2200. For example, the nonvolatile memory chips may communicate with the controller 2200 through first through k^{th} channels CH1 through CHk.

Each of the nonvolatile memory chips may be a nonvolatile memory device fabricated using one of the methods described above with reference to FIGS. 1 through 16.

In the example of FIG. 18, a plurality of nonvolatile memory chips are connected to one channel. However, the memory system 2000 can be modified such that one nonvolatile memory chip is connected to one channel.

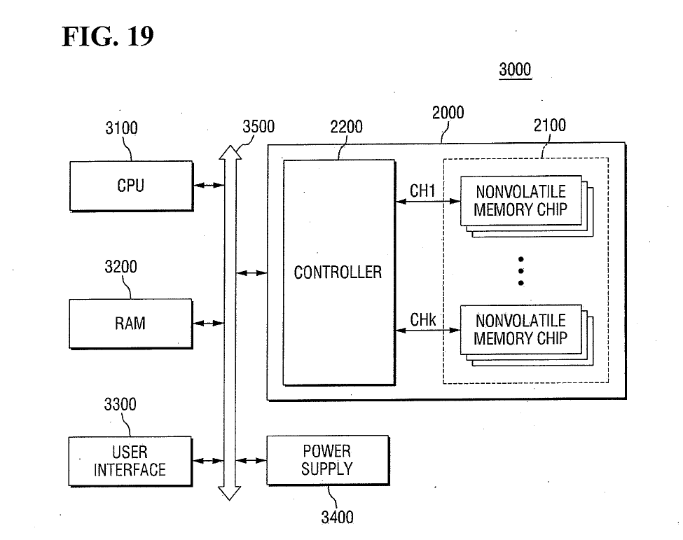

FIG. 19 is a block diagram of a computing system 3000 including the memory system 2000 of FIG. 18.

Referring to FIG. 19, the computing system 3000 includes a central processing unit (CPU) 3100, a RAM 3200, a user interface 3300, a power supply 3400, and a memory system 2000.

The memory system 2000 is electrically connected to the CPU 3100, the RAM 3200, the user interface 3300, and the power supply 3400 through a system bus 3500. Data provided through the user interface 3300 or processed by the CPU 3100 is stored in the memory system 2000.

In FIG. 19, the nonvolatile memory device 2100 is connected to the system bus 3500 through the controller 2200. However, the nonvolatile memory device 2100 can also be connected directly to the system bus 3500.

In FIG. 19, the memory system 2000 described above with reference to FIG. 18 is provided. However, the memory system 2000 can be replaced by the memory system 1000 described above with reference to FIG. 17.

Alternatively, the computing system 3000 may include all of the memory systems 1000 and 2000 described above with reference to FIGS. 17 and 18.

In concluding the detailed description, those skilled in the art will appreciate that many variations and modifications can be made to the preferred embodiments without substantially departing from the principles of the present inventive concepts. Therefore, the disclosed preferred embodiments of the inventive concepts are used in a generic and descriptive sense only and not for purposes of limitation.

1. A nonvolatile memory device comprising:
a substrate;
a trench in the substrate;
a first gate pattern comprising a first bottom gate electrode having a first portion in the trench and having a second portion on the first portion and protruding in an upward direction relative to an upper surface of the substrate;
a second gate pattern comprising a second gate electrode on the substrate at a side of the first gate pattern and insulated from the first gate pattern;
an inter-pattern spacer on a side of the first gate pattern contacting the second gate pattern; and
an impurity region in the substrate at a side of the first gate pattern opposite the second gate pattern, and overlapping part of the trench.

2. The nonvolatile memory device of claim 1, wherein the trench has a first width, and the second portion of the first bottom gate electrode has a second width, wherein the first width is less than the second width.

3. The nonvolatile memory device of claim 2, wherein the trench is entirely overlapped by the second portion of the first bottom gate electrode.

4. The nonvolatile memory device of claim 1, wherein the impurity region covers at least a portion of a bottom surface of the trench and a side surface of the trench.

5. The nonvolatile memory device of claim 1, wherein the first gate pattern further comprises a first gate insulating layer between the trench and the first portion of the first bottom gate electrode and a first top gate electrode on the first bottom gate electrode, wherein each of the first top gate electrode and the first bottom gate electrode does not overlap the second gate electrode.

6. The nonvolatile memory device of claim 5, wherein the first gate insulating layer is conformally formed in the trench.

7. The nonvolatile memory device of claim 5, wherein the first gate insulating layer comprises a first bottom gate insulating layer on the bottom surface of the trench, wherein the first bottom gate insulating layer is thinnest at regions at which the bottom surface of the trench meets a side surface of the trench.

8. The nonvolatile memory device of claim 5, wherein the first gate pattern further comprises an inter-electrode insulating layer interposed between the first bottom gate electrode and the first top gate electrode, the first gate pattern comprises a memory transistor gate, and the second gate pattern comprises a selection transistor gate.

9. The nonvolatile memory device of claim 1, wherein the first gate pattern further comprises a first gate insulating layer between the trench and the first portion of the first bottom gate electrode, and the second gate pattern further comprises a second gate insulating layer, wherein each of the first gate insulating layer and the second gate insulating layer comprises silicon oxide, and a thickness of the first gate insulating layer is different from a thickness of the second gate insulating layer.

10. The nonvolatile memory device of claim 9, wherein the thickness of the first gate insulating layer is greater than the thickness of the second gate insulating layer.

11. The nonvolatile memory device of claim 1, wherein the first gate pattern further comprises a spacer which is on the substrate adjacent to the impurity region and is at a side surface of the first gate pattern, wherein the trench is overlapped by a portion of the spacer.

12. A nonvolatile memory device comprising:
a substrate;
a first gate pattern comprising: a first bottom gate electrode having a first portion buried in the substrate and a second portion on the substrate; and a first top gate electrode on the first bottom gate electrode;
a second gate pattern comprising a second gate electrode on the substrate adjacent a side of the first gate pattern;
an inter-pattern spacer on a side of the first gate pattern contacting the second gate pattern; and
an impurity region in the substrate at a side of the first gate pattern opposite the second gate pattern, and under at least a portion of the first portion of the first bottom gate electrode,
wherein the first portion of the first bottom gate electrode is narrower than the second portion of the first bottom gate electrode, and wherein a threshold voltage of the second gate pattern is different than a threshold voltage of the first gate pattern.

13. The nonvolatile memory device of claim 12, wherein the first portion of the first bottom gate electrode is entirely overlapped by the second portion.

14. The nonvolatile memory device of claim 12, wherein the substrate comprises a trench formed therein, the first portion of the first bottom gate electrode fills the trench, and the impurity region covers at least a portion of a bottom surface of the trench and a side surface of the trench.

15. The nonvolatile memory device of claim 12, wherein the first bottom gate electrode, the first top gate electrode, and the second gate electrode comprise polysilicon.

16. A nonvolatile memory device comprising:
a substrate having a trench;
a first gate of a memory transistor on the substrate, a first portion of the first gate partially in the trench and partially above the trench; a second portion of the first gate on the first portion and insulated from the first portion by an intergate insulating layer, the first portion of the first gate being insulated from the trench by a first gate insulating layer;
a second gate of a selection transistor on the substrate at a side of the first gate, the second gate insulated from the first gate by a blocking insulating layer, and the second gate insulated from the substrate by a second gate insulating layer;
an inter-pattern spacer on a side of the first gate pattern contacting the second gate pattern; and
an impurity region in the substrate at a side of the trench, the impurity region positioned at a side of the first gate opposite the second gate.

17. The nonvolatile memory device of claim 16 wherein the trench has a bottom and a sidewall and wherein the impurity region is further positioned in the substrate at the sidewall and at least a portion of the bottom of the trench so that the portion of the first portion of the first gate that is partially in the trench is at least partially on the impurity region.

18. The nonvolatile memory device of claim 16 wherein the first gate insulating layer and the second gate insulating layer have different thicknesses.

19. The nonvolatile memory device of claim 16 wherein the first portion of the first gate comprises a charge storage region of the memory transistor and wherein the second portion of the first gate comprises a control gate of the memory transistor.

20. The nonvolatile memory device of claim 16 wherein the trench has a bottom and a sidewall and wherein the first gate insulating layer is relatively thinner at a region of the trench where the bottom and sidewall interface.
